(19) United States
(12) Patent Application Publication
(10) Pub. No.: US 2012/0189869 A1
(43) Pub. Date: Jul. 26, 2012

(54) COATED ARTICLE HAVING ANTIBACTERIAL EFFECT AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CONG LI, Shenzhen City (CN)

(73) Assignees: HON HAI PRECISION INDUSTRY CO. LTD., Tu-Cheng (TW); HONG FU JIN PRECISION INDUSTRY (ShenZhen) CO., LTD, Shenzhen City (CN)

(21) Appl. No.: 13/210,742

(22) Filed: Aug. 16, 2011

(30) Foreign Application Priority Data
Jan. 24, 2011 (CN) 201110025900.8

(51) Int. Cl. B32B 15/04; C23C 14/14; C23C 14/08; B32B 7/02; C23C 14/35

(52) U.S. Cl. 428/622; 428/469; 428/216; 428/336; 204/192.15

(57) ABSTRACT

A coated article is described. The coated article includes a substrate, a plurality of zinc layers and a plurality of zinc oxide layers formed on the substrate. Each zinc layer interleaves with one zinc oxide layer. One of the zinc layers is formed on the substrate. One of the zinc oxide layers forms an outermost layer of the coated article. A method for making the coated article is also described.

### CROSS-REFERENCE TO RELATED APPLICATIONS

This application is one of the four related co-pending U.S. patent applications listed below. All listed applications have the same assignee. The disclosure of each of the listed applications is incorporated by reference into the other listed applications.

| Attorney | | |
|---|---|---|
| Docket No. | Title | Inventors |
| US 37031 | COATED ARTICLE HAVING | HSIN-PEI |
| | ANTIBACTERIAL EFFECT AND METHOD | CHANG |
| | FOR MAKING THE SAME | et al. |
| US 39203 | COATED ARTICLE HAVING | HSIN-PEI |
| | ANTIBACTERIAL EFFECT AND METHOD | CHANG |
| | FOR MAKING THE SAME | et al. |
| US 39206 | COATED ARTICLE HAVING | HSIN-PEI |
| | ANTIBACTERIAL EFFECT AND METHOD | CHANG |
| | FOR MAKING THE SAME | et al. |
| US 40773 | COATED ARTICLE HAVING | HSIN-PEI |
| | ANTIBACTERIAL EFFECT AND METHOD | CHANG |
| | FOR MAKING THE SAME | et al. |

### BACKGROUND

1. Technical Field

The present disclosure relates to coated articles, particularly to a coated article having an antibacterial effect and a method for making the coated article.

2. Description of Related Art

To make the living environment more hygienic and healthy, a variety of antibacterial products have been produced by coating substrates of the products with antibacterial metal films. The metal may be copper (Cu), zinc (Zn), or silver (Ag). However, the metal ions within the metal films rapidly dissolve from killing bacterium, so the metal films have a short lifespan.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of a coated article.

FIG. 2 is an overhead view of an exemplary embodiment of a vacuum sputtering device.

### DETAILED DESCRIPTION

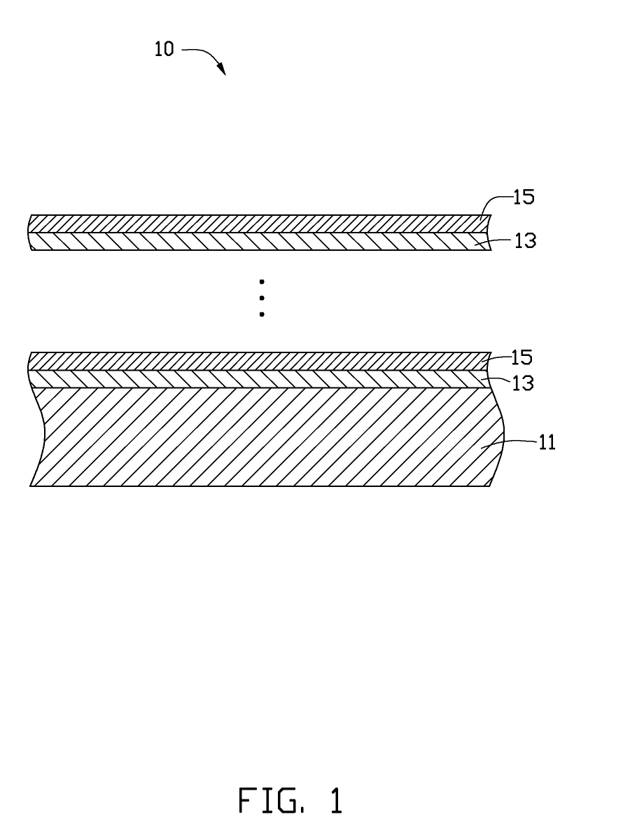

FIG. 1 shows a coated article 10 according to an exemplary embodiment. The coated article 10 includes a substrate 11, a plurality of zinc (Zn) layers 13 and a plurality of zinc oxide (ZnO) layers 15 formed on the substrate 11. Each Zn layer 13 alternates/interleaves with one ZnO layer 15. One of the Zn layers 13 is directly formed on the substrate 11. One of the ZnO layers 15 forms the outermost layer of the coated article 10. The total thickness of the Zn layers 13 and the ZnO layers 15 may be about 1 μm-3 μm. The total number of the Zn layers 13 may be about 10 layers to about 20 layers. The total number of the ZnO layers 15 may be also about 10 layers to about 20 layers.

The substrate 11 may be made of stainless steel, but is not limited to stainless steel.

The Zn layers 13 may be formed by vacuum sputtering. Each Zn layer 13 may have a thickness of about 50 nm-100 nm. The Zn layers 13 have antibacterial properties.

The ZnO layers 15 may be formed by vacuum sputtering. Each ZnO layer 15 may have a thickness of about 50 nm-100 nm. The ZnO layers 15 inhibit the zinc ions of the Zn layers 13 from rapidly dissolving, so the Zn layers 13 have long-lasting antibacterial effect. Additionally, the ZnO layers 15 will increase the concentration of the antibacterial zinc ions, which further enhances and prolongs the antibacterial effect of the coated article 10.

A method for making the coated article 10 may include the following steps:

The substrate 11 is pre-treated, such pre-treating process may include the following steps:

The substrate 11 is cleaned in an ultrasonic cleaning device (not shown) filled with ethanol or acetone.

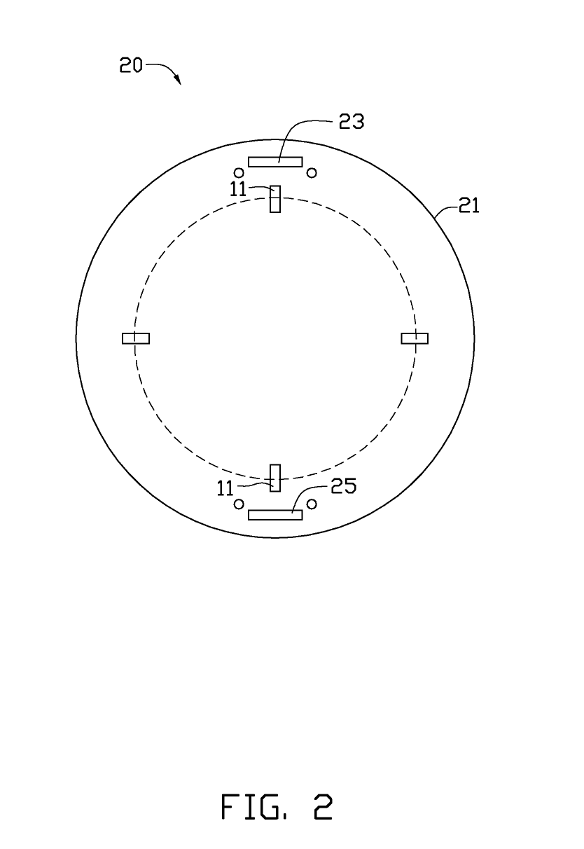

The substrate 11 is plasma cleaned. Referring to FIG. 2, the substrate 11 may be positioned in a coating chamber 21 of a vacuum sputtering device 20. The coating chamber 21 is fixed with zinc (Zn) targets 23 and zinc oxide (ZnO) targets 25. The coating chamber 21 is then evacuated to about 4.0×10⁻³ Pa. Argon gas (Ar) having a purity of about 99.999% may be used as a working gas and is fed into the coating chamber 21 at a flow rate of about 500 standard-state cubic centimeters per minute (sccm). The substrate 11 may have a bias voltage of about −200 V to about −800 V, then high-frequency voltage is produced in the coating chamber 21 and the argon gas is ionized to plasma. The plasma then strikes the surface of the substrate 11 to clean the surface of the substrate 11. Plasma cleaning of the substrate 11 may take about 3 minutes (min)-10 min. The plasma cleaning process enhances the bond between the substrate 11 and the Zn layers 13. The Zn targets 23 and the ZnO targets 25 are unaffected by the pre-cleaning process.

One of the Zn layers 13 may be magnetron sputtered on the substrate 11 by using the zinc targets 23. Magnetron sputtering of the Zn layer 13 is implemented in the coating chamber 21. The coating chamber 21 is evacuated to about 8.0×10⁻³ Pa. The internal temperature of the coating chamber 21 is heated to about 60° C.-100° C. Argon gas may be used as a working gas and is fed into the coating chamber 21 at a flow rate of about 300 sccm-500 sccm. A direct current power of about 5 KW-7 KW is applied on the zinc targets 23, and the zinc atoms are sputtered off from the zinc targets 23 to deposit on the substrate 11 and form the Zn layer 13. During the depositing process, the substrate 11 may have a bias voltage of about −50 V to about −100 V. Depositing of the Zn layer 13 may take about 5 min-8 min.

One of the ZnO layers 15 may be magnetron sputtered on the Zn layer 13 by using the ZnO targets 25. Magnetron sputtering of the ZnO layer 15 is implemented in the coating chamber 21. The internal temperature of the coating chamber 21 is maintained at about 60° C.-100° C. Argon gas may be used as a working gas and is fed into the coating chamber 21 at a flow rate of about 180 sccm-250 sccm. A radio frequency power of about 1 KW-1.5 KW is applied on the ZnO targets 25, then molecular ZnO is sputtered off from the ZnO targets 25 to deposit on the Zn layer 13 and form the ZnO layer 15. During the depositing process, the substrate 11 may have a coupled pulse bias voltage of about −180 V to about −350 V. The coupled pulse bias voltage has a pulse frequency of about 10 KHz and a pulse width of about 20 μs. Depositing of the ZnO layer 15 may take about 8 min-10 min.

The steps of magnetron sputtering the Zn layer 13 and the ZnO layer 15 are repeated about 9-19 times to form the coated article 10.

Specific examples of making the coated article 10 are described as follows. The pre-treating process of ultrasonic and plasma cleaning the substrate 11 in these specific examples may be substantially the same as previously described so it is not described here again. Additionally, the magnetron sputtering processes of Zn layer 13 and ZnO layer 15 in the specific examples are substantially the same as described above, and the specific examples mainly emphasize the different process parameters of making the coated article 10.

### Example 1

The substrate 11 is made of stainless steel.

Sputtering to form Zn layer 13 on the substrate 11: the flow rate of Ar is 420 sccm; the substrate 11 has a bias voltage of −50 V; the Zn targets 23 are applied with a power of 5 KW; the internal temperature of the coating chamber 21 is 60° C.; sputtering of the Zn layer 13 takes 6 min; the Zn layer 13 has a thickness of 62 nm.

Sputtering to form ZnO layer 15 on the Zn layer 13: the flow rate of Ar is 180 sccm; the substrate 11 has a coupled pulse bias voltage of −250 V; the ZnO targets 25 are applied with a power of 1.5 KW; the internal temperature of the coating chamber 21 is 60° C.; sputtering of the ZnO layer 15 takes 10 min; the ZnO layer 15 has a thickness of 80 nm.

The step of sputtering the Zn layer 13 is repeated 19 times, and the step of sputtering the ZnO layer 15 is repeated 19 times.

### Example 2

The substrate 11 is made of stainless steel.

Sputtering to form Zn layer 13 on the substrate 11: the flow rate of Ar is 300 sccm; the substrate 11 has a bias voltage of −75 V; the Zn targets 23 are applied with a power of 7 KW; the internal temperature of the coating chamber 21 is 85° C.; sputtering of the Zn layer 13 takes 8 min; the Zn layer 13 has a thickness of 86 nm.

Sputtering to form ZnO layer 15 on the Zn layer 13: the flow rate of Ar is 250 sccm; the substrate 11 has a coupled pulse bias voltage of −180 V; the ZnO targets 25 are applied with a power of 1 KW; the internal temperature of the coating chamber 21 is 85° C.; sputtering of the ZnO layer 15 takes 10 min; the ZnO layer 15 has a thickness of 68 nm.

The step of sputtering the Zn layer 13 is repeated 19 times, and the step of sputtering the ZnO layer 15 is repeated 19 times.

An antibacterial performance test has been performed on the coated articles 10 described in the above examples 1-2. The test was carried out as follows:

Bacteria was firstly dropped on the coated article 10 and then covered by a sterilization film and put in a sterilization culture dish for about 24 hours at a temperature of about 37±1° C. and a relative humidity (RH) of more than 90%. Secondly, the coated article 10 was removed from the sterilization culture dish, and the surface of the coated article 10 and the sterilization film were rinsed using 20 milliliter (ml) wash liquor. The wash liquor was then collected in a nutrient agar to inoculate the bacteria for about 24 hours to 48 hours at about 37±1° C. After that, the number of surviving bacteria was counted to calculate the bactericidal effect of the coated article 10.

The test result indicated that the bactericidal effect of the coated article 10 with regard to escherichia coli, salmonella, and staphylococcus aureus was no less than 99.99%. Furthermore, after having been immersed in water for about three months at about 37±1° C., the bactericidal effect of the coated article 10 on escherichia coli, salmonella, and staphylococcus aureus was no less than 95%.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
a plurality of alternating zinc layers and zinc oxide layers formed on the substrate, one of the zinc layers being formed on the substrate, and one of the zinc oxide layers forming an outermost layer of the coated article.

2. The coated article as claimed in claim 1, wherein the substrate is made of stainless steel.

3. The coated article as claimed in claim 1, wherein each zinc layer has a thickness of about 50 nm-100 nm.

4. The coated article as claimed in claim 1, wherein each zinc oxide layer has a thickness of about 50 nm-100 nm.

5. The coated article as claimed in claim 1, wherein the zinc layers and the zinc oxide layers have a total thickness of about 1 μm-3 μm.

6. A method for making a coated article, comprising:
providing a substrate;
forming a zinc layer on the substrate by vacuum sputtering, using a zinc target;
forming a zinc oxide layer on the zinc layer by vacuum sputtering, using a zinc oxide target; and
alternately repeating the steps of forming the zinc layer and the zinc oxide layer to form the coated article with one of the zinc oxide layers forming an outermost layer of the coated article.

7. The method as claimed in claim 6, wherein forming the zinc layer uses a magnetron sputtering method; the zinc target is applied with a direct current power of about 5 KW-7 KW; uses argon as a working gas, the argon has a flow rate of about 300 sccm-500 sccm; magnetron sputtering of the zinc layer is conducted at a temperature of about 60° C.-100° C. and takes about 5 min-8 min.

8. The method as claimed in claim 7, wherein the substrate has a bias voltage of about −50V to about −100V during magnetron sputtering of the zinc layer.

9. The method as claimed in claim 6, wherein forming the zinc oxide layer uses a magnetron sputtering method; the zinc oxide target is applied with a radio frequency power of about 1 KW-1.5 KW; uses argon as a working gas, the argon has a flow rate of about 180 sccm-250 sccm; magnetron sputtering of the zinc oxide layer is conducted at a temperature of about 60° C.-100° C. and takes about 8 min-10 min.

10. The method as claimed in claim 9, wherein the substrate has a coupled pulse bias voltage of about −180V to about −350V during magnetron sputtering of the zinc oxide layer.

11. The method as claimed in claim 10, wherein the coupled pulse bias voltage has a pulse frequency of about 10 KHz and a pulse width of about 20 μs.

12. The method as claimed in claim 6, wherein the step of repeating the forming of the zinc layer and the zinc oxide layer is carried out about nine times to about nineteen times.

13. The method as claimed in claim 6, wherein the substrate is made of stainless steel.

14. The method as claimed in claim 6, further comprising a step of pre-treating the substrate before forming the zinc layer.

15. The method as claimed in claim 14, the pre-treating process comprises ultrasonic cleaning the substrate and plasma cleaning the substrate.
